(19) United States
(12) Patent Application Publication
(10) Pub. No.: US 2004/0048420 A1
(43) Pub. Date: Mar. 11, 2004

(54) Method for embedding an air dielectric transmission line in a printed wiring board(PCB)

(76) Inventor: Ronald Brooks Miller, Newark, CA (US)

Correspondence Address: Ronald B. Miller, 1721 Sunset Avenue, Newark, CA, 94560, US

(21) Appl. No.: 10/601,464

(22) Filed: Jun. 23, 2003

Related U.S. Application Data
(60) Provisional application No. 60/391,021, filed on Jun. 25, 2002.

(51) Int. Cl. H01L 21/44

(52) U.S. Cl. 438/127; 29/846; 29/847; 438/106

(57) ABSTRACT

An air dielectric printed circuit board fabrication method is disclosed based on the principles of suspended substrate transmission lines as used in microwave assemblies.

The transmission line conductor is on a thin dielectric layer suspended in air between two conductive planes. The ground in the area around the transmission line may be cut back either by milling or by photo-etching to preclude shorting the transmission line.

### RELATED APPLICATIONS

The present application claims priority from U.S. Provisional Application No. 60/391,021 filed on Jun. 25, 2002 for Method for making an air dielectric transmission line in a printed wiring board by Ronald Brooks Miller.

U.S. patent application Ser. No. 10/094,761 filed Mar. 11, 2002, Publication no. 2003/0001698 A1 “Transmission structure with an Air Dielectric” describes an air dielectric transmission structure with dielectric cut-outs to provide partial air dielectric.

The notable differences between the cited invention and this invention are:

1. The cited invention is for an assembly made from dielectric spacer layers with cut-out areas for air, while this invention is primarily for metallic spacer layers which can be readily manufactured in standard PCB fabrication process.

2. The cited invention is for a structure, whereas this invention is for a laminated PCB.

3. The cited invention uses arbitrary located cut-outs in the dielectric while this invention uses a channel that follows the signal trace where ever it goes.

4. Wheras the cited invention uses a dielectric spacer, this invention uses dielectric materials plated or otherwise covered with metal to mimic a solid piece of metal in order to shield the trace for improved EMI performance

U.S. patent application Ser. No. 10/015,985 filed Nov. 2, 2001, Publication no 2002/0125967 A1, “An Air Dielectric Backplane Interconnection System” describes a backplane with an open transmission line insulated from main backplane using a series of dielectric spacers.

The notable differences between the cited Invention and this invention is that:

1. The cited invention describes an assembly external to a PCB, the backplane, whereas this invention describes a method of embedding the transmission line into the PCB itself.

U.S. patent application Ser. No. 09/751,944 filed on Jan. 2, 2001 by Kim et al, publication no 2001/0015684, “Circuit Board, and method of Manufacturing Therefore” describes a transmission line on the outside of a printed circuit board with supports which hold the line up from the board creating a partial air dielectric for that line and different methods for manufacturing it.

The notable difference between the cited invention and this invention is that whereas the cited invention describes a transmission line on the outside of the printed circuit board this invention is for an internal line with air dielectric. Also, whereas the manufacture of the cited board relies on plating and building up the several layers and then removing them to expose an air transmission line, this board focuses on the shaping of the metal plates used for shielding and positioning the dielectric carrier which is then assembled or laminated with the dielectric layers which is nearly continuous across the planar surface. The dielectric layer carries the signal traces.

U.S. Pat. application Ser. No. 09/997,937 filed on Dec. 3, 2001 by David Lee, publication no 2003/0102249 A1, “Method and Apparatus for an Air-Cavity Package.” describes a method for encapsulating a PCB with many individually packaged components installed in an air-cavity to form a multi-component assembly.

The cited patent does not address the design or manufacture of the PCB as does the present patent.

U.S. patent application Ser. No. 10-162,277 filed on Jun. 3, 2002 by Noel A. Lopez publication no 2002/0186090 A1, “Method and apparatus for low loss High Radio Frequency Transmission” describes high frequency transmission system using suspended substrate transmission line for coupling several stages of a radio transmission system.

The present patent is not for a radio transmission system but is intended primarily for high speed digital or analog systems.

The cited patent does not address how the design in great detail but leaves implementation undefined. Typically in high frequency equipment suspended substrate is accomplished by sandwiching a piece of circuit board between metal plates and screwing them together.

The present patent is different in that the suspended substrate is embedded in the circuit board.

U.S. patent application Ser. No. 09/752,059 filed on Dec. 29, 2000 by Michael Wright publication no 2002/0084876 A1, “Slotted Ground Plane for Controlling the Impedance of High Speed Signals on a Printed Circuit Board”, describes using cut-outs in the ground plane of several shapes in order to raise the impedance of a trace on a particular layer, with no air dielectric used. No claim is made for improved electrical performance other than raising or varying the impedance.

The present patent in contrast uses air as the primary dielectric on these high speed lines, and has several other beneficial performance features.

U.S. patent application Ser. No. 09/794,066 filed on Feb. 28, 2001 by Albert Pergande publication no 2002/0118083 A1, “Millimeterwave Module Compact Interconnect” describes a method for interconnecting modules using an aperture cut in a ground plane as a coupling medium, for millimeter wavelength applications, and has nothing whatsoever to do with air dielectric printed circuit boards. Whereas the present patent focuses on air dielectric printed circuit boards.

U.S. patent application Ser. No. 09/963,641 filed on Sep. 27, 2001 by Yuichi Koga publication no 2002/0050870 A1, “Printed Board, Method for Producing the same and Electronic Device having the same, describes a method for equalizing the propagation time of traces with differing lengths in the same printed circuit board by using different dielectric constants and trace widths. The present patent focuses on air dielectric printed circuit boards.

U.S. Pat. No. 6,247,939 B1 issued on Jun. 19, 2001 by Bestul et al, “Connector for making multiple pressed co-axial connections having an air dielectric” describes a method of making an air dielectric connection vertically through a board board laying flat with a pin or in this case with pogo-pins connecting from top to bottom. Since the present patent deals with traces running through the board in a flat dimension with the board laying flat there is no conflict.

U.S. Pat. No. 7,712,607 issued on Jan. 27, 1998 by Dittmer, et al, “Air-Dielectric Stripline” describes a method for making a PCB with a partial air dielectric by the inclusion of dielectric spacers laminated into the board. In contrast, the present patent deals with an entire metal layer with the metal removed or absent in some places to provide an air dielectric.

U.S. Pat. No. 5,966,103 issued on Oct. 12, 1999, by Pons et al, “Electromagnetic lens of the printed circuit type with a suspended strip line” describes the making of a lens on suspended substrate.

The important differences between this cited patent and the present patent are:

Sited patent deals with a lense where the present patent does not.

and the present patent deals with a suspended line imbedded within a PCB where the cited patent does not.

U.S. Pat. No. 4,614,922 issued on Sep. 20, 1986 by Bauman describes a delay line or a microwave transmission line constructed of discrete plates and a PCB to make up a suspended substrate assembly for use in the Radio or RF domain.

The important difference between this patent and the cited patent is:

Cited patent is made from discrete components whereas this patent is for a PCB assembly.

Cited patent is for microwave, or RF usage while this patent is for a analog and high-speed digital usage.

U.S. Pat. No. 6,518,844 issued on Feb. 11, 2003 by Sherman et al. “Suspended transmission line with embedded amplifier” describes the integration of an assembly of an amplifier or other circuit, with a suspended transmission line assembly.

The cited patent applies to use in the Radio, Microwave and Radar fields. The novelty of this invention is the integration of an amplifier or other discrete circuit into a discretely assembled Suspended Substrate package.

All Claims of the cited patent are for an amplifier or other discrete assembly integrated into a transmission line assembly for RF applications.

In contrast, this patent is for a PCB with improved performance high-speed analog and digital performance.

U.S. Pat. No. 6,535,088 issued on Mar. 18, 2003 by Sherman et al. “suspended transmission line and Method”

Is similar to U.S. Pat. No. 6,518,844 by Sherman, with the the only difference being that:

The cited patent does not use an embedded amplifier or assembly,

The cited patent is different from U.S. Pat. No. 4,614,922 by Bauman only in that

the assembly uses a top and bottom trace on the carrier connected together at several points

Claim 1 that it is a method for transmitting a signal at a specified frequency.

The figures and most of the detailed text are identical to U.S. Pat. No. 6,518,844

Accordingly, this patent is different from U.S. Pat. No. 6,535,088 in that this one:

only uses one signal trace as in the origional patent by Bauman above contrasted with the cited patent claim using two traces tied together at several points.

Is a PCB(not discrete) for the interconnection of digital and analog signals. contrasted with the cited patent claim for transmitting a signal at a specified frequency.

U.S. Pat. No. 6,542,048 issued on Apr. 1, 2003 by Sherman et al. “Suspended Transmission Line with Signal Channeling Device” is similar to U.S. Pat. No. 6,518,844 by Sherman, and differs only in that a signal channeling device (microwave power divider) is implemented in the transmission lines.

The present patent is different from the patent cited in the same way that it is different from U.S. Pat. No. 6,535,088.

U.S. Pat. No. 6,552,635 issued on Apr. 22, 2003 by Sherman eta al. “Integrated Broadside Conductor for Suspended Transmission Line and Method” is similar to 6,535,088 and is different only in that no amplifier is embedded in it.

The present patent is different from the patent cited in the same way that it is different from U.S. Pat. No. 6,535,088.

### BACKGROUND

1. Field of the Invention

The present invention relates to a PCB design for application in analog and high speed digital applications using a air-dielectric suspended substrate. This will allow improved signal integrity, lower bit-error-rate, better eye pattern and higher-speed data signals.

2. Description of the Related Art—the Need

Electronic data rates are ever increasing. Today we have gigahertz data rates and looking to terrahertz data rates in the future. Also, size reduction and cost reduction is constantly being pressed.

Some of the technical problems associated with designing and fabricating reliable interconnect of devices at these frequencies are:

1. High Frequency attenuation

2. Degradation of state transitions(dispersion of signal edge)

3. Delay in the signal from one place to another

4. Eye pattern distortion and closure

5. Data errors.

6. Group delay

7. Reflections

These problems can be caused by the following factors

1. The dielectric loss tangent

2. Frequency dependency of loss tangent

3. The dielectric Constant

4. Frequency dependency of dielectric constant

5. Skin effect

6. Crosstalk

7. Impedance variations

8. Frequency dependency of impedance variations(stubs etc.)

By using air as the primary dielectric, the dielectric constant and the dielectric loss tangent are at the optimal values, namely 1 and 0. Also, since the trace is surrounded by a metal shield nearly all crosstalk is eliminated.

The remaining degradation to the signal is:

skin effect which cannot be improved without increasing the size and

impedance variations which are geometry based.

### Suspended Substrate—a Possible Answer

Definition: Suspended substrate, is a mechanical means for mounting a thin substrate with a conductive trace between two conductive planes with an air dielectric between the trace and the top and bottom conductive planes.

### Microwave Implimentation:—Historical

In the past Suspended Substrate was used in RF and Microwave applications. The implimentation method was to sandwich the substrate layer between the top and bottom conductive planes, with channels milled into the conductive planes above and below the trace, so that the trace would not short out to the planes.

The top and bottom plates are milled images of each other.

One or more signal traces are positioned between the plates by a thin dielectric carrier layer.

The milling in the conductive planes forms an air channel which follows the conductive traces.

The channel is wider than the conductive trace to ensure that the traces are not connected or shorted to the planes.

The milling is to a controlled depth.

The top and bottom conductive planes and the dielectric carrier layer are connected mechanically and electrically together using nuts and bolts.

When viewing the traces from the edge of the structure the trace rides on a thin dielectric membrane in an air channel surrounded by a conductor, mimicking a coaxial structure.

### PCB Implementation of Suspended Substrate—this Patent is the Answer

Several methods for improving the signal integrity in Printed Circuit Boards(PCB's), by the use of embedded air dielectric suspended on a thin dielectric are mentioned in the claims above. The most cost effective means to improve the performance is to use a metal layer as a spacer with metal removed to preclude shorting the signal trace. The metal can be easily removed by several inexpensive methods.

### SUMMARY OF INVENTION

Air used as a dielectric has the lowest dissipation factor and the lowest dielectric constant of all dielectric materials. Since the dissipation factor is nearly zero, the high frequency losses in the dielectric are nearly eliminated, and for high frequency signals, the dominant remaining losses are skin effect and radiation losses. Since the dielectric constant of air is essentially one (1) the velocity of propagation is nearly the speed of light.

In contrast standard PCB materials have dielectric losses which are the dominant loss factor above 1 or 2 Ghz. The skin effect and radiation are the same as in air but being a smaller percentage of the total loss. Also, typical PCB materials have a dielectric factor ranging from 2 to 4, which results in the propagation through the board being reduced to 1/sqrt(dielectric factor) or from 0.7 or 0.5 which alternatively stated, the delay is increased by 50 percent to about 100 percent of the velocity in air.

Both the dielectric constant and the dielectric loss factor are frequency dependent which causes dispersion of the transition from one voltage state to another. The result is deformed and extended rise-time and fall-time, and jitter in the eye pattern. This results in data errors and poor bit-error-rates.

In order to use air as the primary dielectric in a PCB, a structure resembling suspended substrate is used. A metal trace is suspended in air on a thin dielectric much like a road on a bridge across a large air space is suspended. The bridge being the thin dielectric, the road being the trace, and the air being the air above and below.

In the PCB, two conductive planes, one above and one below provide the signal return, reference and shielding. These two planes may be power or ground planes but are not required to be power or ground.

The air dielectric is typically formed by adding spacing layers above and below the thin dielectric layer supporting the signal trace. Conductive planes above and below the spacers provide the AC ground return for the signal on the signal trace. The spacing material may be either conductive, resistive, or insulated, and need not be uniform in composition. The spacing may also be made by milling or otherwise forming an indentation to insulate the conductive planes from the traces, by any process including, but not limited to etching, plating, milling, punching, drawing, forming, or stamping

The dielectric layer(s) is(are) laminated with the formed metal planes, or the metal planes with the metal spacer layer.

A simple method for making interconnect(vias) is to drill oversized holes in the metal planes or spacers before lamination. Add dielectric to fill the oversized holes either before, or after lamination. After lamination, via holes are drilled and plated as in standard PCB processing.

A mixture of standard PCB layers and air dielectric layers can be used as needed within the same PCB. Adhesive sheets, or coatings may be used to adhere the metal layers together. Thin adhesive material has no degrading effects because if it is conductive the metal shell is conductive and if it is not, the capacitance across the gap will be make it appear to be connected for all high-speed signals.

### Improved Performance

The PCB will have much better impedance control compared to standard PCB tolerances for two reasons. First, the depth tolerance of can be much better controlled than the tolerance of standard dielectric material which flows and is non-uniform compared with sheet metal spacer that sets the spacing. Secondly, the dielectric constant of air one and does not vary, compared with standard materials which vary across a broad range.

The use of air dielectric provides a very low dielectric loss factor for high frequency, microwave and high speed digital signals up into the gigahertz and gigabit frequencies, compared to standard dielectric materials.

The use of air dielectric provides the shortest time delay or the fastest transition time for a given trace length, compared to standard dielectric materials. Epoxy fiberglass material has a delay of approximately 2× the free space velocity of light while this application of air dielectric can approach the free space velocity of light.

Air dielectric also minimizes the dispersion of the transition of the signal from one voltage to another caused by frequency dependent dielectric losses and phase shift which are not present in air.

The use of air dielectric increases the trace impedance for traces with the same width to height ratio by a factor of approximately 2. Alternatively stated, for a given impedance and trace width, the height may be reduced by a factor of approximately 2.

Where a data-bus or non-synchronous signals share the same channel, the cross-talk from signal to signal within the same channel can be reduced by the use of an air dielectric and by reducing the height spacing of the trace to the metal plate compared to the cross-talk of a strip-line transmission line with the same impedance and the same spacing of traces.

### BRIEF DESCRIPTION OF THE DRAWINGS

FIG. 1 shows an expanded orthogonal view of a cross section of a single layer of signal suspended in air per claim 1 for the purposes of envisioning the invention. The assembly is made by laminating the three layers together.

FIG. 2 shows the basic structure of claim 1 with (1) a top metal plate, (2) a central dielectric layer, and (2) a bottom metal plates. The conductive trace on the central dielectric is located in the middle of the channel in the two metal plates.

FIG. 3 is similar to FIG. 2 in all respects except that the top metal plate is made up of a top plane or shield, and a spacer plate.

### DESCRIPTION OF THE PREFERRED EMBODIMENT

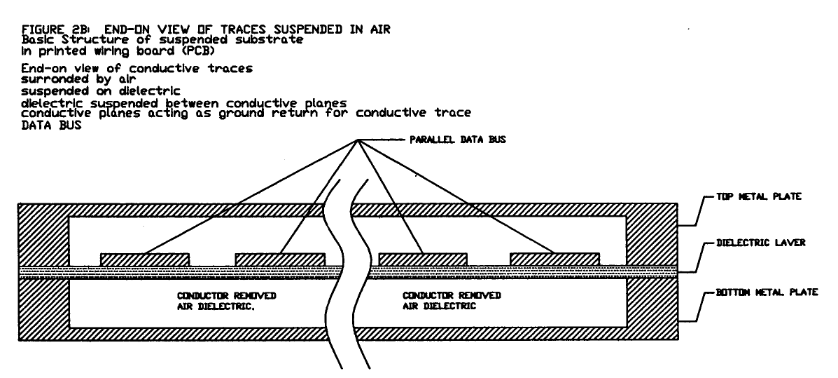

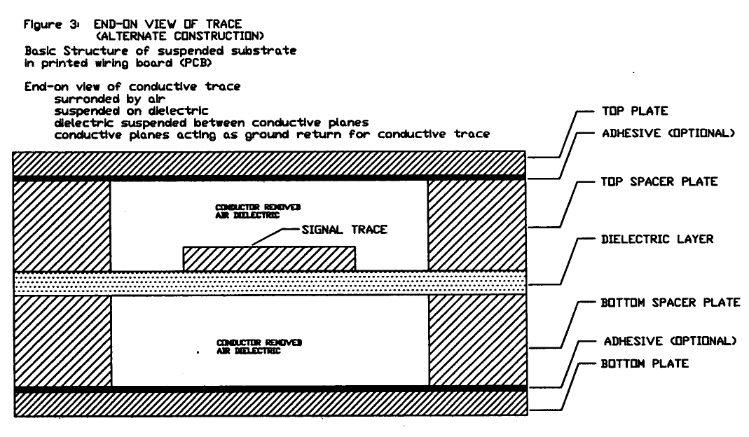

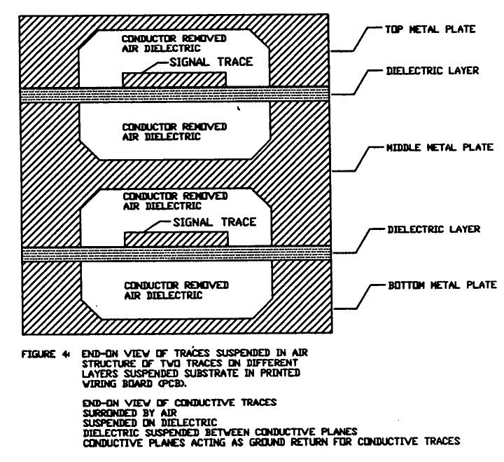

The most likely embodiment at the present time is the configuration of FIG. 2 with the top conductive layer and bottom conductive layer being a sheet of 1 mill copper. The two spacer layers would be photo-etched metal approximately 4 mils thick available from several vendors. The signal trace will be approximately 6 mils wide on a dielectric layer of FR4 approximately 1 mil thick. The channel will be approximately 10 mills wide. The impedance will be approximately 50 ohms and will have a transit time approximately 90% of the speed of light, and an RF attenuation attributable only to skin effect and DC loss.

Via preparation will use oversize drilling of the metal sheets, filling these drill holes with dielectric material by squeegee or by pressing, and curing the dielectric. At this point standard PCB fabrication and assembly will begin complete the process.

### BRIEF DESCRIPTION OF THE DRAWINGS

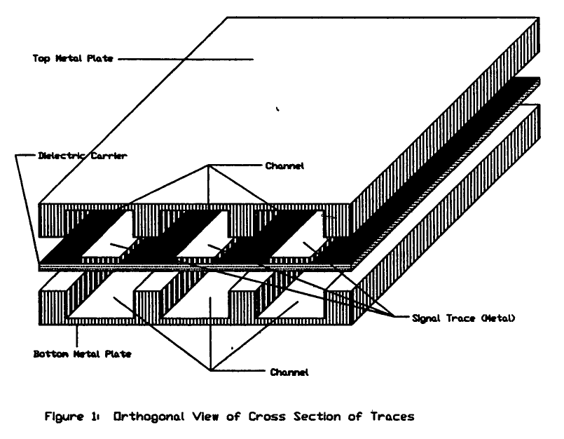

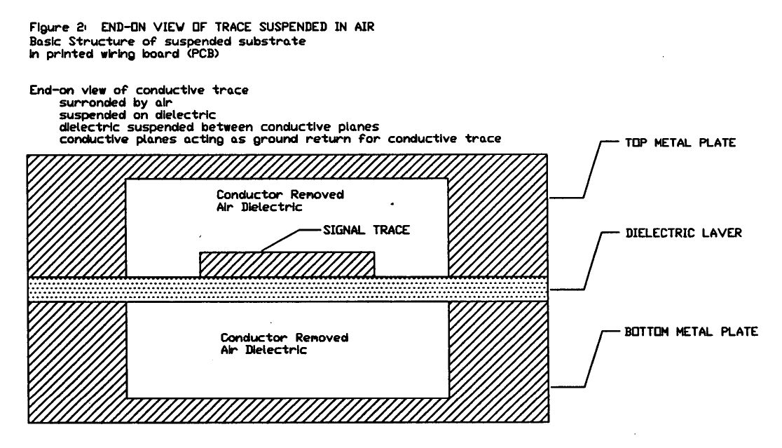

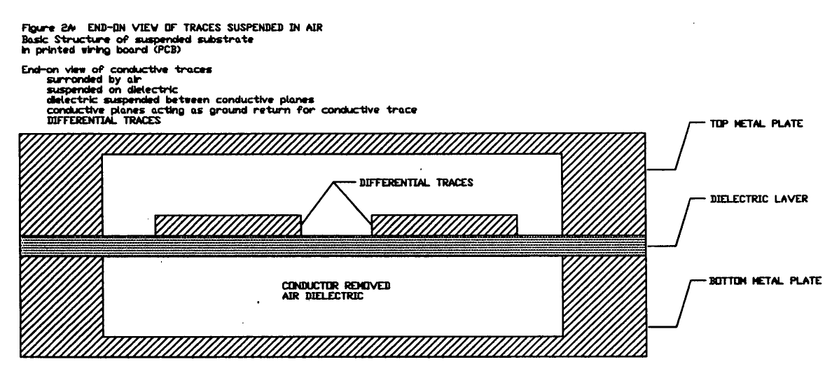

FIG. 1 is an expanded orthogonal view of one layer with three parallel lines intended to help in visualizing how the signal trace is suspended in air riding on the dielectric carrier. Note that the top channels are mirror image of the bottom channels so that when the assembly is laminated the trace is in a shielded enclosure.

The metal plates have the metal removed, most likely by milling or forming or some other method depending on cost.

Also, note that the dielectric carrier layer is thin and provides a virtual short due to the capacitance from one plate to the other.

FIG. 2 is an end-on view of a single air dielectric trace in the metal channels.

FIG. 2A is an end-on view of a differential pair in air dielectric

FIG. 2B is an end-on view of a 4 signal data-bus in air dielectric

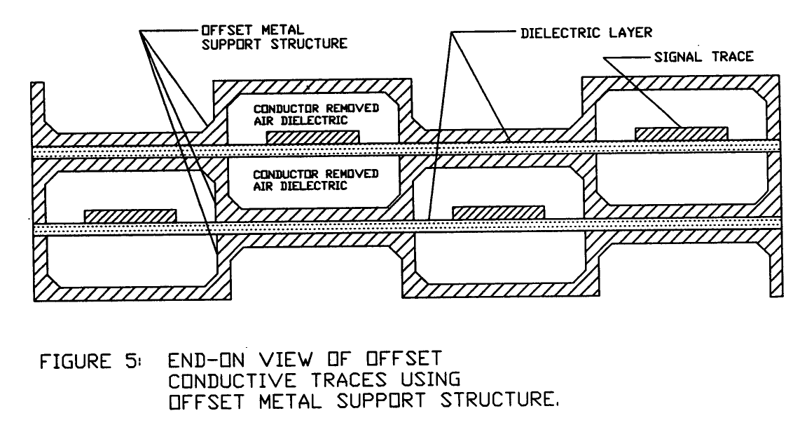

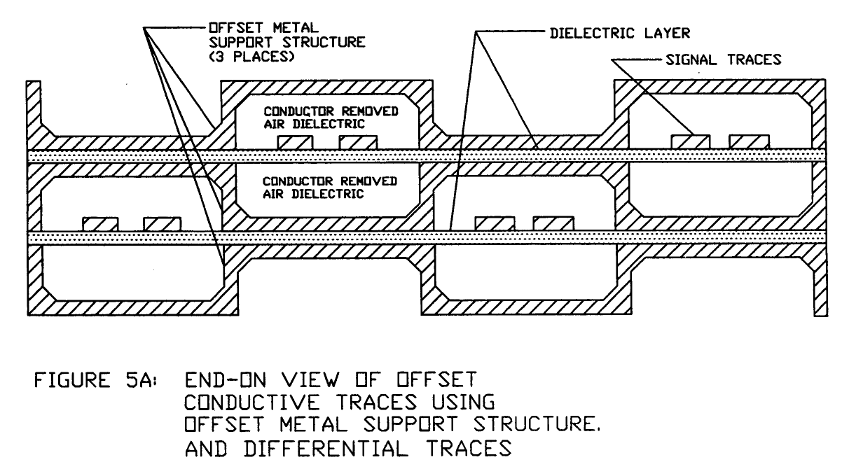

FIG. 3 is an alternative fabrication method using separate spacer layers and top and bottom shields.

An adhesive may be either applied to the metal or may be a sheet.

The advantage of this method that the spacing from signal trace to the top and bottom plate is precisely determined by the thickness of the spacer layer, at very little cost but provides very accurate impedance control.

FIG. 4 illustrates:

The stacking of multiple layers of air-dielectric assembly.

The use of a single metal plate between dielectric layers.

And can be applied to any other combination such as differential pairs and data busses.

FIG. 5 illustrates an offset method of construction for a multi-layer assembly:

For improved signal trace density

With cost effective forming or stamping possible with sheet metals.

FIG. 5A

illustrates a offset construction method

combined with differential traces.

### DETAILED DESCRIPTION OF THE INVENTION

### Cost Saving

The present invention of embedding an air dielectric in a PCB is targeted at analog and digital markets with highly improved performance at minimum cost differential compared to standard PCB manufacture. In fact, the material cost will be lower than required using standard materials and techniques.

The impedance of all the applications and figures used in this invention is especially uniform through the structure, both from layer to layer, and from trace to trace on the same layer because we do not deal with a dielectric material which varies in thickness, in dielectric constant and loss factor from piece to piece, from batch to batch, from location to location on the same laminate, but only with the thickness of metal sheet or foil which is rolled to very tight tolerances.

The manufacture of standard PCBs with impedance controlled within 10% typically adds 20 percent to the cost of the boards and tolerances tighter than 7% are not obtainable except at huge cost premiums. The reason for this cost premium is that the partially laminated board must be tested for impedance, the etching time and material selection adjusted to make up for material variations and finally assembled. No process adjustment can make up for variations in thickness and material across the board.

This invention will make possible the manufacture of boards with impedances controlled under 5 percent standard, and 2 percent economically practical when needed.

### Loadboards

In the digital applications, the first focus is on assemblies like “test boards” and “load boards”, used in automatic test equipment(ATE). The time delay of these boards, typically 3 to 5 nS, can nearly be cut in half, which means twice as many devices can be tested in a given time on a given tester. Since the testers typically cost between 1 and 5 million dollars, the value proposition of these boards is enormous.

Loadboards would normally use FIG. 1, FIG. 2, and FIG. 3 as the simplest method for making completely isolated test signal traces.

### Personal Computers

Secondly, in digital applications, the PCI bus comes to mind. The PCI bus is limited in its speed by reflections because it is an un-terminated bus. So, the set-time requirement is long, requiring that the signal and its reflections settle out to a stable state before the receiving device can latch the data with the clock. Accordingly, when the delay of the signal up and down the bus is shorter the settling of the data to a stable state can occur faster. The use of air-dielectric can cut this delay in half, and increase the speed by two.

Since the bottle-neck in increasing the speed of personal computers is not the processor or the memory, but the PCI bus, this can have a huge effect in improving the performance and should make personal computers an even better cost to value proposition.

On the PCI bus several parallel traces parallel can be encompassed within a single channel in the metal plates.

Cross-talk between traces of the data bus is reduced by using air-dielectric because for a given impedance and trace width, the height can be reduced by a factor of SQRT(0.5) or about 0.7. As the height between the ground-planes is reduced the cross-talk from trace to trace is also reduced by about half.

PCI would normally use a configuration similar to FIG. 2B with 4 or more traces per channel. Using 8 or more traces might cause manufacturing yields to drop if the channel height becomes compressed from lamination.

Other parallel data busses would use similar structures.

### High Speed Differential Signals

High speed differential signals, especially at 1 Gigahertz and above suffer excess attenuation from standard dielectric materials and dispersion of the signal transitions, which limit the length they can traverse a PCB. Using air-dielectric can allow much longer traces for the same performance or better performance for the same trace lengths.

In some high speed digital PCB Assemblies, trace compensation using pre-emphasis at the driving end of the signals, passive equalization, or receive end signal equalization hardware is used.

The use of air-dielectric will in many applications make trace compensation unnecessary in many cases, simplifying design and reducing costs.

FIG. 2A illustrates a typical method of implementing a differential trace on a high speed PCB. Such a trace should provide satisfactory performance for 4 inch traces or more up to 10 GBS, compared to 2 inches in FR4.

### Motherboards and Backplanes

Backplanes and motherboards require very high-density interconnect with minimum spacing and maximum trace lengths, and are subject to maximum crosstalk and external EMI.

FIG. 5 shows 4 signal traces mounted on two dielectric layers traversing a honeycomb structure made up of formed metal corrugations offset to pass the signal traces without shorting. This arrangement provides maximum trace density, minimum crosstalk, minimum signal degradation and is impervious to external EMI, and allows minimum radiated EMI.

For High-Speed Differential traces within a motherboard or backplane, FIG. 5A illustrates an optimum solution

### BACKGROUND

### Description of the Related Art—the Need

Electronic data rates are ever increasing. Today we have gigahertz data rates and looking to terrahertz data rates in the future. Also, size reduction and cost reduction is constantly being pressed.

Some of the technical problems associated with designing and fabricating reliable interconnect of devices at these frequencies are:

1. High Frequency attenuation

2. Degradation of state transitions(dispersion of signal edge)

3. Delay in the signal from one place to another

4. Eye pattern distortion and closure

5. Data errors.

6. Group delay

7. Reflections

These problems can be caused by the following factors

1. The dielectric loss tangent

2. Frequency dependency of loss tangent

3. The dielectric Constant

4. Frequency dependency of dielectric constant

5. Skin effect

6. Crosstalk

7. Impedance variations

8. Frequency dependency of impedance variations(stubs etc.)

By using air as the primary dielectric, the dielectric constant and the dielectric loss tangent are at the optimal values, namely 1 and 0. Also, since the trace is surrounded by a metal shield nearly all crosstalk is eliminated.

The remaining degradation to the signal is:

skin effect which cannot be improved without increasing the size and

impedance variations which are geometry based.

### Suspended Substrate—a Possible Answer

Definition: Suspended substrate, is a mechanical means for mounting a thin substrate with a conductive trace between two conductive planes with an air dielectric between the trace and the top and bottom conductive planes.

### Microwave Implimentation:—Historical

In the past Suspended Substrate was used in RF and Microwave applications. The implimentation method was to sandwich the substrate layer between the top and bottom conductive planes, with channels milled into the conductive planes above and below the trace, so that the trace would not short out to the planes.

The top and bottom plates are milled images of each other.

One or more signal traces are positioned between the plates by a thin dielectric carrier layer.

The milling in the conductive planes forms an air channel which follows the conductive traces.

The channel is wider than the conductive trace to ensure that the traces are not connected or shorted to the planes.

The milling is to a controlled depth.

The top and bottom conductive planes and the dielectric carrier layer are connected mechanically and electrically together using nuts and bolts.

When viewing the traces from the edge of the structure the trace rides on a thin dielectric membrane in an air channel surrounded by a conductor, mimicking a coaxial structure.

### PCB Implementation of Suspended Subetrat—this Patent is the Answer

Several methods for improving the signal integrity in Printed Circuit Boards(PCB's), by the use of embedded air dielectric suspended on a thin dielectric are mentioned in the claims above. The most cost effective means to improve the performance is to use a metal layer as a spacer with metal removed to preclude shorting the signal trace. The metal can be easily removed by several inexpensive methods.

### SUMMARY OF INVENTION

Air used as a dielectric has the lowest dissipation factor and the lowest dielectric constant of all dielectric materials. Since the dissipation factor is nearly zero, the high frequency losses in the dielectric are nearly eliminated, and for high frequency signals, the dominant remaining losses are skin effect and radiation losses. Since the dielectric constant of air is essentially one (1) the velocity of propagation is nearly the speed of light.

In contrast standard PCB materials have dielectric losses which are the dominant loss factor above 1 or 2 Ghz. The skin effect and radiation are the same as in air but being a smaller percentage of the total loss. Also, typical PCB materials have a dielectric factor ranging from 2 to 4, which results in the propagation through the board being reduced to 1/sqrt(dielectric factor) or from 0.7 or 0.5 which alternatively stated, the delay is increased by 50 percent to about 100 percent of the velocity in air.

Both the dielectric constant and the dielectric loss factor are frequency dependent which causes dispersion of the transition from one voltage state to another. The result is deformed and extended rise-time and fall-time, and jitter in the eye pattern. This results in data errors and poor bit-error-rates.

In order to use air as the primary dielectric in a PCB, a structure resembling suspended substrate is used. A metal trace is suspended in air on a thin dielectric much like a road on a bridge across a large air space is suspended. The bridge being the thin dielectric, the road being the trace, and the air being the air above and below.

In the PCB, two conductive planes, one above and one below provide the signal return, reference and shielding. These two planes may be power or ground planes but are not required to be power or ground.

The air dielectric is typically formed by adding spacing layers above and below the thin dielectric layer supporting the signal trace. Conductive planes above and below the spacers provide the AC ground return for the signal on the signal trace. The spacing material may be either conductive, resistive, or insulated, and need not be uniform in composition. The spacing may also be made by milling or otherwise forming an indentation to insulate the conductive planes from the traces, by any process including, but not limited to etching, plating, milling, punching, drawing, forming, or stamping

The dielectric layer(s) is(are) laminated with the formed metal planes, or the metal planes with the metal spacer layer.

A simple method for making interconnect(vias) is to drill oversized holes in the metal planes or spacers before lamination. Add dielectric to fill the oversized holes either before, or after lamination. After lamination, via holes are drilled and plated as in standard PCB processing.

A mixture of standard PCB layers and air dielectric layers can be used as needed within the same PCB. Adhesive sheets, or coatings may be used to adhere the metal layers together. Thin adhesive material has no degrading effects because if it is conductive the metal shell is conductive and if it is not, the capacitance across the gap will be make it appear to be connected for all high-speed signals.

### Improved Performance

The PCB will have much better impedance control compared to standard PCB tolerances for two reasons. First, the depth tolerance of can be much better controlled than the tolerance of standard dielectric material which flows and is non-uniform compared with sheet metal spacer that sets the spacing. Secondly, the dielectric constant of air one and does not vary, compared with standard materials which vary across a broad range.

The use of air dielectric provides a very low dielectric loss factor for high frequency, microwave and high speed digital signals up into the gigahertz and gigabit frequencies, compared to standard dielectric materials.

The use of air dielectric provides the shortest time delay or the fastest transition time for a given trace length, compared to standard dielectric materials. Epoxy fiberglass material has a delay of approximately 2× the free space velocity of light while this application of air dielectric can approach the free space velocity of light.

Air dielectric also minimizes the dispersion of the transition of the signal from one voltage to another caused by frequency dependent dielectric losses and phase shift which are not present in air.

The use of air dielectric increases the trace impedance for traces with the same width to height ratio by a factor of approximately 2. Alternatively stated, for a given impedance and trace width, the height may be reduced by a factor of approximately 2.

Where a data-bus or non-synchronous signals share the same channel, the cross-talk from signal to signal within the same channel can be reduced by the use of an air dielectric and by reducing the height spacing of the trace to the metal plate compared to the cross-talk of a strip-line transmission line with the same impedance and the same spacing of traces.

### BRIEF DESCRIPTION OF THE DRAWINGS

FIG. 1 shows an expanded orthogonal view of a cross section of a single layer of signal suspended in air per claim 1 for the purposes of envisioning the invention. The assembly is made by laminating the three layers together.

FIG. 2 shows the basic structure of claim 1 with (1) a top metal plate,(2) a central dielectric layer, and(2) a bottom metal plates. The conductive trace on the central dielectric is located in the middle of the channel in the two metal plates.

FIG. 3 is similar to FIG. 2 in all respects except that the top metal plate is made up of a top plane or shield, and a spacer plate.

### DESCRIPTION OF THE PREFERRED EMBODIMENT

The most likely embodiment at the present time is the configuration of FIG. 2 with the top conductive layer and bottom conductive layer being a sheet of 1 mill copper. The two spacer layers would be photo-etched metal approximately 4 mils thick available from several vendors. The signal trace will be approximately 6 mils wide on a dielectric layer of FR4 approximately 1 mil thick. The channel will be approximately 10 mills wide. The impedance will be approximately 50 ohms and will have a transit time approximately 90% of the speed of light, and an RF attenuation attributable only to skin effect and DC loss.

Via preparation will use oversize drilling of the metal sheets, filling these drill holes with dielectric material by squeegee or by pressing, and curing the dielectric. At this point standard PCB fabrication and assembly will begin complete the process.

### BRIEF DESCRIPTION OF THE DRAWINGS

FIG. 1 is an expanded orthogonal view of one layer with three parallel lines intended to help in visualizing how the signal trace is suspended in air riding on the dielectric carrier. Note that the top channels are mirror image of the bottom channels so that when the assembly is laminated the trace is in a shielded enclosure.

The metal plates have the metal removed, most likely by milling or forming or some other method depending on cost.

Also, note that the dielectric carrier layer is thin and provides a virtual short due to the capacitance from one plate to the other.

FIG. 2 is an end-on view of a single air dielectric trace in the metal channels.

FIG. 2A is an end-on view of a differential pair in air dielectric

FIG. 2B is an end-on view of a 4 signal data-bus in air dielectric

FIG. 3 is an alternative fabrication method using separate spacer layers and top and bottom shields.

An adhesive may be either applied to the metal or may be a sheet.

The advantage of this method that the spacing from signal trace to the top and bottom plate is precisely determined by the thickness of the spacer layer, at very little cost but provides very accurate impedance control.

FIG. 4 illustrates:

The stacking of multiple layers of air-dielectric assembly.

The use of a single metal plate between dielectric layers.

And can be applied to any other combination such as differential pairs and data busses.

FIG. 5 illustrates an offset method of construction for a multi-layer assembly:

For improved signal trace density

With cost effective forming or stamping possible with sheet metals.

FIG. 5A

illustrates a offset construction method

combined with differential traces.

### DETAILED DESCRIPTION OF THE INVENTION

### Cost Saving

The present invention of embedding an air dielectric in a PCB is targeted at analog and digital markets with highly improved performance at minimum cost differential compared to standard PCB manufacture. In fact, the material cost will be lower than required using standard materials and techniques.

The impedance of all the applications and figures used in this invention is especially uniform through the structure, both from layer to layer, and from trace to trace on the same layer because we do not deal with a dielectric material which varies in thickness, in dielectric constant and loss factor from piece to piece, from batch to batch, from location to location on the same laminate, but only with the thickness of metal sheet or foil which is rolled to very tight tolerances.

The manufacture of standard PCBs with impedance controlled within 10% typically adds 20 percent to the cost of the boards and tolerances tighter than 7% are not obtainable except at huge cost premiums. The reason for this cost premium is that the partially laminated board must be tested for impedance, the etching time and material selection adjusted to make up for material variations and finally assembled. No process adjustment can make up for variations in thickness and material across the board.

This invention will make possible the manufacture of boards with impedances controlled under 5 percent standard, and 2 percent economically practical when needed.

### Loadboards

In the digital applications, the first focus is on assemblies like “test boards” and “load boards”, used in automatic test equipment(ATE). The time delay of these boards, typically 3 to 5 nS, can nearly be cut in half, which means twice as many devices can be tested in a given time on a given tester. Since the testers typically cost between 1 and 5 million dollars, the value proposition of these boards is enormous.

Loadboards would normally use FIG. 1, FIG. 2, and FIG. 3 as the simplest method for making completely isolated test signal traces.

### Personal Computers

Secondly, in digital applications, the PCI bus comes to mind. The PCI bus is limited in its speed by reflections because it is an un-terminated bus. So, the set-time requirement is long, requiring that the signal and its reflections settle out to a stable state before the receiving device can latch the data with the clock. Accordingly, when the delay of the signal up and down the bus is shorter the settling of the data to a stable state can occur faster. The use of air-dielectric can cut this delay in half, and increase the speed by two.

Since the bottle-neck in increasing the speed of personal computers is not the processor or the memory, but the PCI bus, this can have a huge effect in improving the performance and should make personal computers an even better cost to value proposition.

On the PCI bus several parallel traces parallel can be encompassed within a single channel in the metal plates.

Cross-talk between traces of the data bus is reduced by using air-dielectric because for a given impedance and trace width, the height can be reduced by a factor of SQRT(0.5) or about 0.7. As the height between the ground-planes is reduced the cross-talk from trace to trace is also reduced by about half.

PCI would normally use a configuration similar to FIG. 2B with 4 or more traces per channel. Using 8 or more traces might cause manufacturing yields to drop if the channel height becomes compressed from lamination.

Other parallel data busses would use similar structures.

### High Speed Differential Signals

High speed differential signals, especially at 1 Gigahertz and above suffer excess attenuation from standard dielectric materials and dispersion of the signal transitions, which limit the length they can traverse a PCB. Using air-dielectric can allow much longer traces for the same performance or better performance for the same trace lengths.

In some high speed digital PCB Assemblies, trace compensation using pre-emphasis at the driving end of the signals, passive equalization, or receive end signal equalization hardware is used.

The use of air-dielectric will in many applications make trace compensation unnecessary in many cases, simplifying design and reducing costs.

FIG. 2A illustrates a typical method of implementing a differential trace on a high speed PCB. Such a trace should provide satisfactory performance for 4 inch traces or more up to 10 GBS, compared to 2 inches in FR4.

### Motherboards and Backplanes

Backplanes and motherboards require very high-density interconnect with minimum spacing and maximum trace lengths, and are subject to maximum crosstalk and external EMI.

FIG. 5 shows 4 signal traces mounted on two dielectric layers traversing a honeycomb structure made up of formed metal corrugations offset to pass the signal traces without shorting. This arrangement provides maximum trace density, minimum crosstalk, minimum signal degradation and is impervious to external EMI, and allows minimum radiated EMI.

For High-Speed Differential traces within a motherboard or backplane, FIG. 5A illustrates an optimum solution

What is claimed is

1. A PCB with internal signal traces on a thin dielectric layer suspended in air between two flat metal plates. Suspension in air is accomplished by indentation of the flat metal plates above and below the trace and a distance away from the edges of the trace, leaving the remainder of the metal away from the indentation to act as a spacer. The indented area is referred to as a “channel”. See FIG. 1 for orthogonal view and FIG. 2 for end-on view.

2. The PCB of claim 1 fabricated by removal of material in the metal plate by etching, milling, punching or shaping or any other method

3. The PCB of claim 1 fabricated by adding material to the metal plate using buy not limited to plating, welding, electro-plating, painting, spraying, or assembly or any other metal build-up process.

4. The PCB of claim 1 fabricated by assembling a combination of metal plates with at least one one plate essentially electrically continuous over the assembly, and at least one metal spacing plate with metal removed from the trace area to keep from shorting the signal. The metal spacing plate(s) may be made by etching, milling punching or any process.

5. The PCB of claim 1 fabricated by shaping of material in the metal plate by but not limited to stamping, drawing or other process. The ridges and valleys of one side can become the valleys and ridges of the opposite side, for the next layer stacked.

6. The PCB of claim 1 fabricated by casting, molding, electro-forming or any similar process to make the metal plate in the desired shape. The ridges and valleys of one side can become the valleys and ridges of the opposite side, for the next layer stacked.

7. The PCB of claim 1 with dielectric layer strong enough to support the trace between the spacing layers but thin enough to minimize the effect it will have on the composite dielectric constant including the air between the trace and the external conductive planes.

8. The PCB of claim 1 wherein several traces may be used on the same dielectric layer in individual channels.

9. The PCB of claim 1 wherein several traces may be placed within a single channel.

10. The PCB of claim 1 wherein two traces may be placed to operate as a differential pair of signals.

11. The PCB of claim 1 wherein Multiple layers are stacked so that many traces can be routed in the same PCB.

12. single metal plate of claim 1 may have metal indentation on the opposite surface so that the plate serves two different signal traces, one above and one below.

13. The PCB of claim 1 will be 4 or 5 mils thick spacers, conductive layers will be about 1 mil thick, copper trace will be about 1 mils thick and the overall section will be about 12 mils.

14. The PCB of claim 1 wherein channels in the metal plates noted above may be extended to the edges of the PCB or to holes to the surface to provide for air escape or inflow if temperature or altitude changes might cause compression or expansion of trapped air and de-lamination.

15. The PCB of claim 1 wherein attachment of vias for traces of claim 1 may be by (1) removing the dielectric layer with signal trace,(2) drilling a hole larger than the via in the metal plates and spacers, (3) forcing dielectric material into the drill hole in the metal plates individually, (4) laminating the layers together, (5) drilling a smaller via hole through the dielectric material and the pads on the signal trance and (6) plating to connect the via to the signal trace as is normally done.

16. The PCB of claim 1 wherein attachment of vias of claim 1 may be done using several techniques Including the insertion of dielectric spacers or metal pins to electrically connect and to position the connection via.

17. The PCB of claim 1 wherein laminating metal to metal may use an adhesive coating or an adhesive sheet. The adhesive will have no effect on electrical high speed performance because the thin dielectric of the adhesive with wide metal plates forms a high frequency capacitive short from top to bottom plates.
